(19) United States
(12) Patent Application Publication
(10) Pub. No.: US 2019/0393105 A1
(43) Pub. Date: Dec. 26, 2019

(54) PROTECTIVE COATING ON PHOTORESIST FOR PHOTORESIST METROLOGY

(71) Applicant: Lam Research Corporation, Fremont, CA (US)

(72) Inventors: Jea L. Cho, Fremont, CA (US); Daniel Anthony Simon, San Jose, CA (US); Andrew D. Bailey, III, Milpitas, CA (US)

(21) Appl. No.: 16/015,096

(22) Filed: Jun. 21, 2018

(51) Int. Cl. H01L 21/66; H01L 21/027; H01L 21/02; G03F 7/16; C23C 16/40; C23C 16/455

(52) U.S. Cl. CPC H01L 22/12; H01L 21/0273; H01L 21/02274; H01L 21/0228; H01L 21/0217; C23C 16/401; C23C 16/45536; H01L 21/02164; G03F 7/167

(57) ABSTRACT

Photoresist features can be characterized by electron microscopy-based metrology. A protective coating may be deposited on the photoresist with no change or minimal change to the dimensions of the underlying photoresist features, where the protective coating may be conformal and formed in a reactor operated under low temperature and low plasma conditions. In some implementations, the protective coating is formed by plasma-enhanced atomic layer deposition. Reliable and accurate profile information of photoresist features can be captured by metrology using the protective coating.

### BACKGROUND

As device and feature sizes continue to shrink in the semiconductor industry, patterning features of small critical dimensions will continue to gain importance in fabrication of advanced integrated circuits (ICs). Greater accuracy and precision are required for lithography patterning and etch processes during the fabrication of semiconductor architectures that have smaller and smaller features and pitches. Even the slightest variation in critical dimension can cause degradation of device performance. Inspections of patterns and/or features may be performed to ensure accuracy and precision of the lithography patterning and etch processes. Inspections or localized measurements may be performed using a metrology tool that involves photon-beam, ion-beam, or electron-beam irradiation. However, photon-beam, ion-beam, or electron-beam irradiation may induce shrinkage and morphology change in photoresist materials, which can result in inaccuracies and errors in the inspection process during semiconductor manufacturing.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of characterizing a photoresist. The method includes receiving a wafer having a photoresist, and conformally depositing a protective coating on the photoresist, where the protective coating is conformally deposited in a reactor operated under conditions with a wafer temperature being less than about 70° C. and a plasma power being less than about 500 W, where depositing the protective coating reduces a feature height of the photoresist by less than about 15%, changes a feature volume of the photoresist by less than about 15%, and/or changes a critical dimension of the photoresist by less than about 15%. The method further includes performing metrology on the photoresist with the protective coating using a metrology tool.

In some implementations, conformally depositing the protective coating on the photoresist includes depositing the protective coating by atomic layer deposition (ALD). Depositing by ALD can include introducing a precursor to adsorb on the photoresist, converting the precursor with a plasma to form an adsorption-limited amount of the protective coating on the photoresist, and repeating operations of introducing the precursor and converting the precursor to conformally deposit the protective coating on the photoresist. In some implementations, converting the precursor with plasma includes flowing an oxygen-containing reactant and/or a nitrogen-containing reactant to the reactor and igniting a plasma to form an oxidizing plasma and/or nitriding plasma. Converting the precursor with plasma may include exposing the precursor to plasma for a duration between about 0.1 seconds and about 1 second. In some implementations, the protective coating includes an oxide, a nitride, or a mixture thereof, the protective coating having a dielectric constant that is different than the photoresist. In some implementations, the protective coating includes silicon oxide (SiOₓ). In some implementations, the metrology tool is selected from the group consisting of: a transmission electron microscope (TEM), a scanning electron microscope (SEM), a scanning transmission electron microscope (STEM), and a critical dimension scanning electron microscope (CDSEM). In some implementations, characterizing the photoresist includes determining a profile of the photoresist for a resist model. In some implementations, the conditions for conformally depositing the protective coating includes the wafer temperature being between about 20° C. and about 60° C., and the plasma power being between about 10 W and about 300 W. In some implementations, performing the metrology and conformally depositing the protective coating occur on a system that includes both the reactor and the metrology tool.

Another aspect involves a system that includes a deposition module, a metrology module, and a controller configured with instructions for performing the following operations: receiving a wafer having a photoresist in the deposition module, conformally depositing a protective coating on the photoresist, where the protective coating is conformally deposited in the deposition module operated under conditions with a wafer temperature being between about 20° C. and about 60° C. and a plasma power being between about 10 W and about 300 W, where conformally depositing the protective coating reduces a feature height of the photoresist by less than about 15%, changes a feature volume of the photoresist by less than about 15%, and/or changes a critical dimension of the photoresist by less than about 15%, and performing metrology on the photoresist with the photoresist in the metrology tool.

These and other aspects are described further below with reference to the drawings.

### BRIEF DESCRIPTION OF THE DRAWINGS

FIG. 1A shows a schematic of a photoresist pattern with electron-beam irradiation on top of a photoresist pattern.

FIG. 1B shows a photoresist cross-sectional shape change caused by electron-beam irradiation on top of a photoresist pattern.

FIG. 2A shows a schematic of a photoresist pattern with electron-beam irradiation in spaces between photoresist features.

FIG. 2B shows a photoresist cross-sectional shape change caused by electron-beam irradiation in spaces between photoresist features.

FIGS. 3A-3E show three-dimensional schematic illustrations in a process of protecting a photoresist pattern when preparing a TEM or STEM sample for metrology.

FIG. 4 shows photoresist profiles computed from various microscopy-based metrology techniques.

FIG. 5 is a flow diagram of an example method for characterizing a photoresist according to some implementations.

FIG. 6 shows a graph of minimum CD and feature height of a photoresist as a function of a number of ALD cycles applied in a non-damaging protective coating on the photoresist.

FIG. 7A shows a TEM image of an oxide protective coating on a photoresist deposited using a thermal ALD process.

FIG. 7B shows a TEM image of an oxide protective coating on a photoresist deposited using a plasma-enhanced ALD process at reduced temperatures.

FIG. 7C shows a TEM image of an oxide protective coating on a photoresist depositing using a plasma-enhanced ALD process at reduced reactant gas flow rates.

FIGS. 8A-8C show TEM images in a multiple patterning process with an electron-beam-based platinum coating on a photoresist.

FIGS. 9A-9C show TEM images in a multiple patterning process with a non-damaging protective coating on a photoresist.

FIG. 10A shows a CDSEM image of photoresist lines on a wafer.

FIG. 10B shows a graph of mean CD measured across three scans of the CDSEM image in FIG. 10A for without a coating and for a non-damaging protective coating.

FIG. 11A shows a CDSEM image of photoresist features on a wafer.

FIG. 11B shows a graph of mean CD measured across three scans of the CDSEM image in FIG. 11A for without a coating and for a non-damaging protective coating.

FIG. 12 shows a schematic diagram of an example plasma processing apparatus for performing atomic layer deposition (ALD) operations.

FIG. 13 shows a top view of a schematic diagram of an example semiconductor process cluster architecture with various modules.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

Photolithography is a common process used to form semiconductor devices and integrated circuits. By way of an illustration, a conventional photolithography technique defines features of a semiconductor device using patterning and etching processes. “Features” as used herein may refer to a non-planar structure on the wafer, typically a surface being modified in a semiconductor device fabrication operation. Examples of features include trenches, vias, pads, pillars, domes, and the like. A feature typically has an aspect ratio (depth or height to width). In photolithography processes, a photoresist material is deposited on a substrate. A soft bake may be applied to the photoresist material to drive off solvent by heating the substrate. The photoresist material is then exposed to light filtered by a photomask (reticle). The reticle is generally a glass plate that is patterned with feature geometries that block light from propagating through the reticle. After passing through the reticle, the light contacts the surface of the photoresist material and changes the chemical composition of the photoresist material such that a developer can remove a portion of the photoresist material. A developer is applied to the photoresist material to remove the portion of the photoresist material. In the case of positive photoresist materials, the exposed regions are removed, and in the case of negative photoresist materials, the unexposed regions are removed. The patterned photoresist material is used as a mask to etch underlying layers.

The characteristics and properties of the photoresist will influence the quality of photolithography patterning processes and etch processes. This is especially important as pattern sizes become smaller and smaller, such as 65 nanometers, 45 nanometers, 32 nanometers, 22 nanometers, 14 nanometers, or below. Various techniques have been employed to improve the precision and resolution capability of photoresist patterns, including techniques such as optical proximity correction (OPC), immersion lithography, extreme ultraviolet (EUV) lithography, and phase shift masks. However, lithography patterning even with such techniques may be insufficient at current critical dimensions.

Performing inspections, obtaining localized measurements, and generating accurate profile images of the photoresist may provide keys to further developing and improving lithography patterning processes and etch processes. A profile of etched features may be strongly dependent on a profile of after-development photoresist patterns. After-development inspections (ADI) may be carried out to determine the profile and verify the quality of the photoresist or photoresist pattern using a metrology tool. A scanning electron microscope (SEM) may be used as a metrology tool for characterizing a photoresist or photoresist pattern. For even higher resolutions, a transmission electron microscope (TEM) or a scanning transmission electron microscope (STEM) may be used to analyze a photoresist or photoresist pattern. Electron microscopy-based inspections may be used to optimize lithography patterning processes and/or etch processes, or at least ensure that the lithography patterning processes and/or etch processes perform as designed.

Polymer materials and carbon-based materials, particularly in photoresists, are vulnerable to shrinkage and morphology changes in thickness and shape from electron-beam irradiation. Electron-beam exposure on photoresist materials induce polymer crosslinking and chain scission, resulting in deformation of the photoresist profile. This introduces distortions, including reductions in feature height and changes in critical dimensions, of the photoresist materials. Moreover, in preparation of TEM and STEM samples, a focused ion beam (FIB) is used to prepare such samples and exposure the photoresist materials to ion-beam irradiation. The ion-beam irradiation causes damage to the photoresist materials and changes the chemical characteristics of the photoresist. The ion-beam irradiation further induces heating of soft materials, which can also result in deformation of the photoresist. Thus, ion-beam and/or electron-beam irradiation from electron microscopy-based inspections may induce damage and deformation to the photoresist that is being inspected. In addition, it is possible that photon-beam irradiation, such as ultraviolet (UV) exposure, can induce damage or deformation to the photoresist. Molecular and ion-cluster beams may also induce damage or deformation to the photoresist. It will be understood that references to beam irradiation as used herein are inclusive of ion beams, electron beams, photon beams, molecular beams, ion-cluster beams, and any other beams associated with metrology.

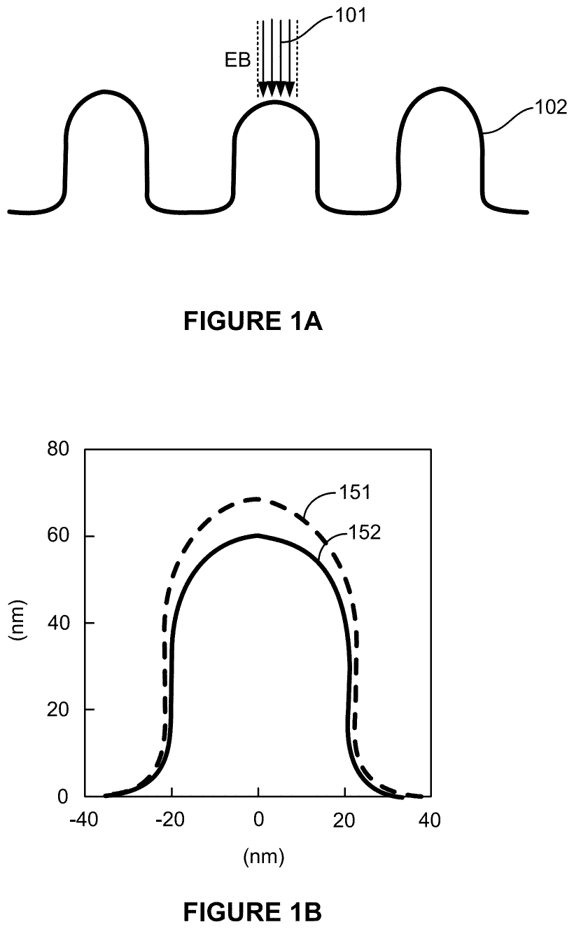

FIG. 1A shows a schematic of a photoresist pattern with electron-beam irradiation on top of the photoresist pattern. A top of a photoresist pattern is exposed to electron-beam irradiation 101 as indicated by arrows. An image the photoresist pattern may be taken from, for example, a TEM or STEM image. The image of the photoresist pattern may provide a photoresist pattern profile 102. FIG. 1B shows a photoresist cross-sectional shape change caused by electron-beam irradiation on top of the photoresist pattern. An ideal photoresist profile 151 is indicated by dashed lines and an electron-beam irradiated photoresist profile 152 is indicated by a solid line. The electron-beam irradiation on top of the photoresist pattern results in a significant decrease in a feature height of the photoresist.

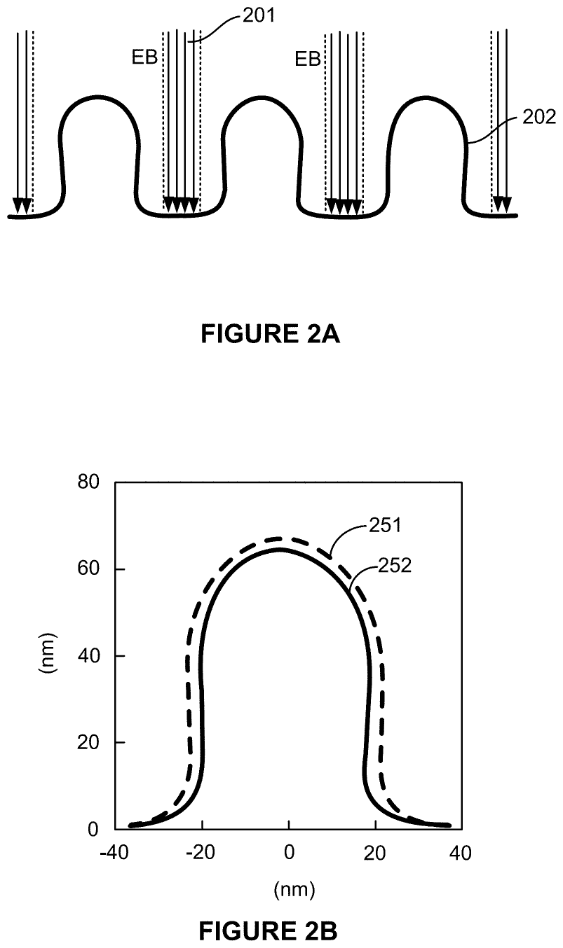

FIG. 2A shows a schematic of a photoresist pattern with electron-beam irradiation in spaces between photoresist features. Spaces in between photoresist features are exposed to electron-beam irradiation 201 as indicated by the arrows. An image of the photoresist pattern may be taken from, for example, a TEM or STEM image. The image of the photoresist pattern may provide a photoresist pattern profile 202. FIG. 2B shows a photoresist cross-sectional shape change caused by electron-beam irradiation in spaces between photoresist features. An ideal photoresist profile 251 is indicated by dashed lines and an electron-beam irradiated photoresist profile 252 is indicated by a solid line. The electron-beam irradiation in the spaces between photoresist features results in measurable sidewall shrinkage and necking of the photoresist.

Methodologies for minimizing electron-beam damage, ion-beam damage, or other beam damage associated with metrology may involve lowering the acceleration voltage and/or decreasing irradiation dose density of the beam. Other methodologies may predict photoresist pattern profiles by calculating the shrinkage and deformation from electron-beam, ion-beam, or other beam irradiation and accounting for such shrinkage and deformation in modeling. Other methodologies may exist for minimizing electron-beam, ion-beam, or other beam damage by providing a protective coating on the photoresist. These protective coatings or films may still induce damage on the underlying photoresist.

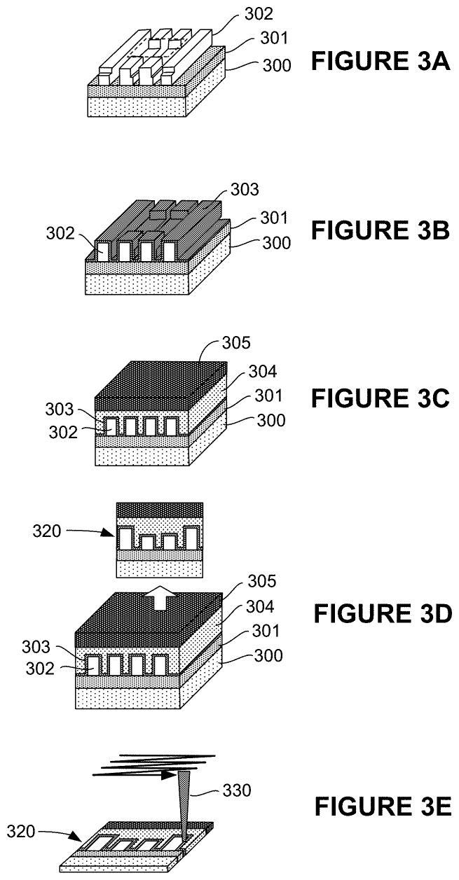

FIGS. 3A-3E show three-dimensional schematic illustrations in a process of protecting a photoresist pattern when preparing a TEM or STEM sample for metrology. In FIG. 3A, a silicon dioxide layer 301 may be formed on a wafer 300. In some implementations, the wafer 300 is a silicon wafer. A pattern of photoresist lines 302 may be formed on the silicon dioxide layer 301. In some implementations, the photoresist lines 302 are positive tone developed (PTD) photoresist lines.

In FIG. 3B, a protective coating 303 may be deposited on the photoresist lines 302. In some implementations, the protective coating 303 may be a conformal thin film that serves to protect the underlying photoresist lines 302 from electron-beam, ion-beam, or other beam damage. The protective coating 303 may coat the photoresist lines 302 without significantly changing the dimensions of features of the photoresist lines 302. For example, the protective coating 303 may avoid shrinking or changing a feature height, a feature volume, and/or a critical dimension of the photoresist lines 302 by 15% or more. In some instances, the protective coating 303 may even avoid shrinking or changing the feature height, the feature volume, and/or the critical dimension of the photoresist lines 302 by 12% or more, or by 10% or more. Many protective coatings or other methodologies for minimizing electron-beam, ion-beam, or other beam damage may induce damage to the underlying photoresist itself, thereby significantly changing the dimensions of features of the photoresist lines 302. However, the protective coating of the present disclosure may protect against electron-beam, ion-beam, or other beam damage and also limit damage to the underlying photoresist itself.

In FIG. 3C, a dielectric layer 304 and a conductive layer 305 may be deposited over the photoresist lines 302 and the protective coating 303. The dielectric layer 304 may be used to protect the photoresist lines 302 from a slicing process of a focused ion beam (FIB) technique and prevent the photoresist lines 302 from collapsing. The conductive layer 305 may serve to isolate the photoresist lines 302 from the ambient environment, avoid any charging effect from electron-beam irradiation or ion-beam irradiation, and further protect the photoresist lines 302 from a slicing process of the FIB technique and prevent pattern collapse. In some implementations, for example, the dielectric layer 304 may include spin-on glass (SOG) or amorphous carbon and the conductive layer 305 may include tungsten (W).

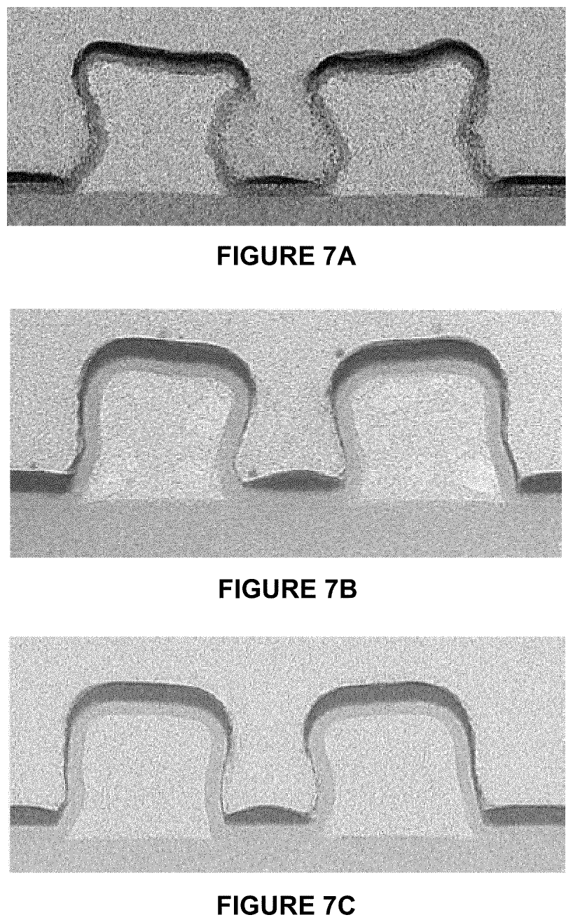

In FIG. 3D, a TEM or STEM sample 320 is prepared by a FIB. In some implementations, the FIB technique may produce the TEM or STEM sample 320 using an ion miller. For example, the FIB technique may use gallium ions (Ga⁺) to prepare the TEM or STEM sample 320. The protective coating 303, the dielectric layer 304, and/or the conductive layer 305 may protect the TEM or STEM sample 320 against ion-beam damage. The TEM or STEM metrology may enable metrology to be conducted in the x-z plane, which is viewed as a cross-section of the wafer 300 showing its aspect ratio and feature profile. Example x-z profiles for features of after-development inspection photoresists are illustrated in FIGS. 7A-7C, 8A-8C, and 9A-9C.

In FIG. 3E, the TEM or STEM sample 320 is observed using an electron microscopy-based metrology. A TEM or STEM image may be generated using electron-beam irradiation 330 through the TEM or STEM sample 320.

A photoresist may be subject to after-development inspection (ADI) metrology and characterization using one of many different metrology tools. Example ADI metrology tools include but are not limited to critical dimension scanning electron microscopy (CDSEM), optical critical dimension (OCD) metrology, and atomic force microscopy (AFM). Other examples include scanning electron microscopy (SEM), cross-sectional scanning electron microscopy (XSEM), transmission electron microscopy (TEM), cross-sectional transmission electron microscopy (XTEM), and scanning transmission electron microscopy (STEM). Some of these metrologies may be conducted in the x-y plane, which is viewed top down onto a wafer and/or from the vantage of the mask, or in the x-z plane, which is viewed as a cross-section of the wafer feature showing its aspect ratio and feature profile.

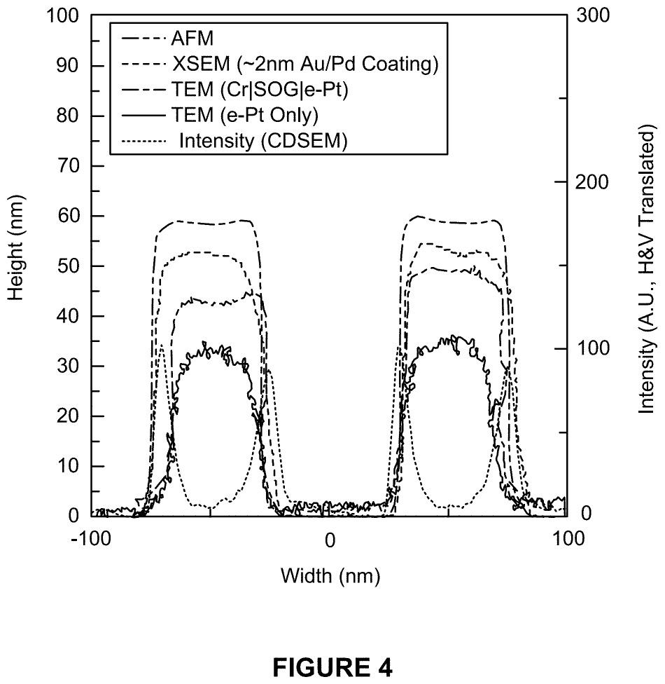

FIG. 4 shows photoresist profiles computed from various microscopy-based metrology techniques. Each of the electron microscopy-based metrology techniques utilized a protective coating or protective material on the photoresist. As shown in FIG. 4, a gold-palladium (Au/Pd) coating may be formed on the photoresist in samples when performing XSEM metrology (labeled ˜2 nm Au/Pd coating), a chromium layer and spin-on glass layer and electron-beam platinum layer may be formed on the photoresist in samples when performing TEM metrology (labeled CrlSOGle-Pt), and an electron-beam platinum layer may be formed on the photoresist in samples when performing TEM metrology (labeled e-Pt Only). AFM metrology uses a probe to determine an original profile of the photoresist and an original feature height of the photoresist, or at least a profile and feature height that is substantially similar to the original profile and the original feature height of the photoresist. AFM metrology does not induce damage or deformation to the photoresist by electron-beam or ion-beam irradiation. Thus, the electron microscopy-based metrology techniques may be compared against the AFM metrology technique. In comparing the photoresist profile using XSEM metrology or TEM metrology against the photoresist profile using AFM metrology, it is observed in FIG. 4 that electron-beam deposition and sputtering of metal films on photoresist induces damage to the photoresist and causes distortion of the original photoresist profile. In addition, the feature height of the photoresist shrinks significantly when using XSEM or TEM metrology compared against the original feature height when using AFM metrology. Specifically, the photoresist feature height difference may shrink from about 60 nm to about 50 nm, to about 40 nm, or to about 30 nm, where the reduction in the photoresist feature height is greater than 15%. Electron-beam deposition and sputtering of metal films on photoresist significantly reduces feature height, reduces critical dimension, and distorts the original profile of the photoresist. The critical dimension of the photoresist can be determined by a distance between peaks from the CDSEM metrology in FIG. 4. In some implementations, the reduction in feature height is greater than 15% or the change in critical dimension is greater than 15%.

Many protective coatings or materials used in electron microscopy-based metrology techniques induce damage, distortion, and deformation to the underlying photoresist. Examples of such results are shown in FIG. 4. The dimensions of the photoresist features and the shape of the photoresist features significantly deviate from the original dimensions and shape. A protective coating of the present disclosure is deposited on photoresist while eliminating or minimizing damage, distortion, and deformation to the underlying photoresist. The protective coating also eliminates or minimizes damage to the underlying photoresist that would otherwise result from an electron microscopy-based metrology technique. Optimal deposition conditions are achieved in the present disclosure for depositing the protective coating without damage or minimizing damage to the photoresist.

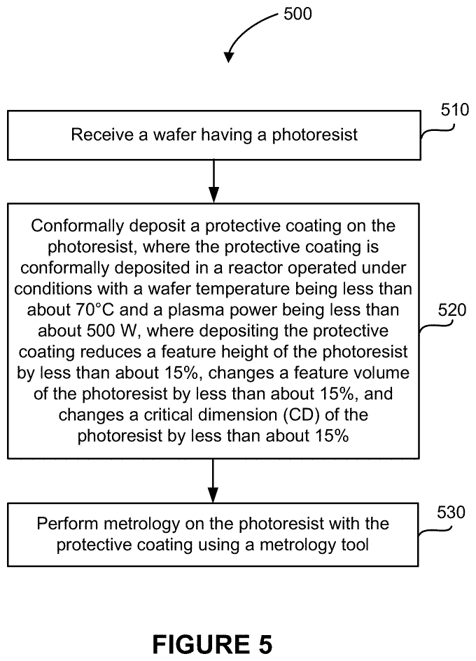

FIG. 5 is a flow diagram of an example method for characterizing a photoresist according to some implementations. The photoresist may be characterized after depositing a protective coating on the photoresist. The operations in a process 500 may be performed in different orders and/or with different, fewer, or additional operations.

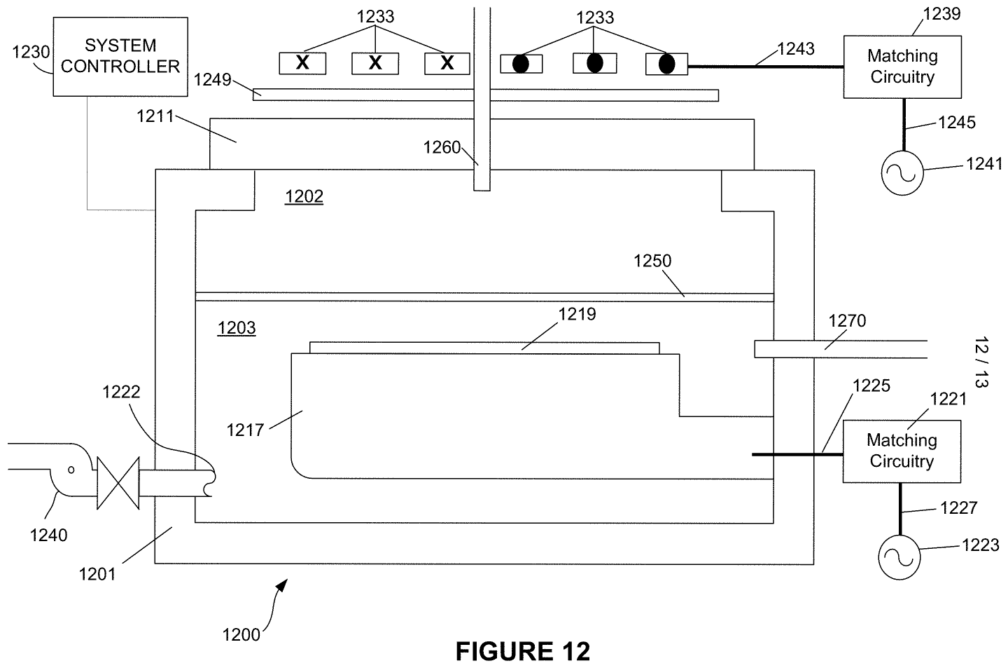

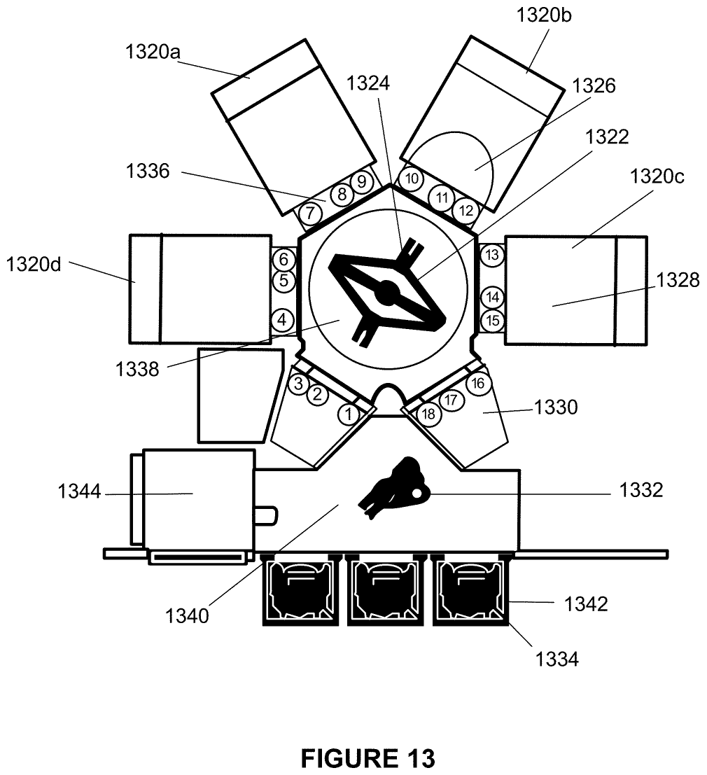

At block 510 of the process 500, a wafer having a photoresist is received. The wafer may be provided to a reactor, where the photoresist includes a photoresist pattern that serves as a mask for patterning underlying layers. Prior to providing the wafer to the reactor, photoresist material may be deposited and patterned to form the photoresist pattern using a photolithography patterning process. An example reactor for receiving the wafer and depositing a protective coating is described below with respect to FIGS. 12 and 13. In some implementations, the reactor for depositing the protective coating is part of a system or apparatus for performing metrology.

In some implementations, the photoresist includes a photoresist material, such as a polymer material or carbon-based material. In some implementations, the photoresist is a positive tone developed photoresist. In some implementations, a critical dimension of the photoresist is equal to or less than about 20 nm.

At block 520 of the process 500, a protective coating is conformally deposited on the photoresist, where the protective coating is conformally deposited in a reactor operated under conditions with a wafer temperature being less than about 70° C. and a plasma power being less than about 500 W, where depositing the protective coating reduces the feature height of the photoresist by less than about 15%, changes a feature volume by less than about 15%, and changes a critical dimension (CD) of the photoresist by less than about 15%. In some implementations, depositing the protective coating reduces the feature height of the photoresist by less than about 12% or less than about 10%, changes a feature volume by less than about 12% or less than about 10%, and changes a CD of the photoresist by less than about 12% or less than about 10%. In some implementations, conformally depositing the protective coating on the photoresist includes depositing the protective coating by atomic layer deposition (ALD).

ALD is a technique that deposits thin layers of material using sequential self-limiting reactions. Typically, an ALD cycle includes operations to deliver and adsorb at least one reactant to the substrate surface, and then react the adsorbed reactant with one or more reactants to form the partial layer of film. Unlike a CVD technique, ALD processes use surface-self-limited deposition reactions to deposit films on a layer-by-layer basis. A typical ALD cycle may include: (i) dosing that delivers and adsorbs precursor material onto a substrate surface in a reactor, (ii) purging excess precursor material from the reactor and leaving a self-limited monolayer on the substrate surface, (iii) delivery of reactant material to react with the adsorbed precursor material in the reactor, and (iv) purging of unreacted reactant material or reaction byproducts from the reactor. The dose step may adsorb precursor material in a self-limiting manner such that once active sites are occupied by the precursor material, little or no additional precursor material will be adsorbed on the substrate surface. The reactant material may likewise react with the precursor material in a self-limiting or absorption-limiting manner. Purge steps may be optionally performed to remove excess precursor material, reaction byproducts, and/or unreacted reactant material from the reactor, completing an ALD cycle. ALD may be used to provide highly conformal films with relatively high step coverage even in high aspect ratio features.

During a dose phase of an ALD cycle, the wafer is exposed to a precursor. The precursor may be introduced into the reactor and may adsorb on the photoresist in a self-limiting manner. The precursor may include a single reagent or mixture of reagents to make the protective coating. In some implementations, the wafer may be exposed to the precursor for a time between about 0.1 seconds and about 60 seconds, or between about 0.2 seconds and about 6 seconds, depending on the flow rate and the wafer surface area. In some implementations, a carrier or diluting gas flows during the dose phase. In some implementations, a purge phase may follow a dose phase, where carrier or diluting gas may continue to flow. Precursor flow is turned off and no plasma is ignited during the purge phase.

During a reactant material delivery phase of the ALD cycle, the wafer is exposed to reactant gas to convert the precursor to form an adsorption-limited amount of the protective coating on the photoresist. Where the ALD process is a plasma-enhanced ALD process, plasma may be ignited during the reactant material delivery phase so that the wafer is exposed to radicals and ions of the reactant gas. In some implementations, an oxygen-containing reactant and/or a nitrogen-containing reactant is flowed towards the wafer and plasma is ignited to form an oxidizing plasma and/or nitriding plasma. The wafer may be exposed to plasma for a duration between about 0.1 seconds and about 60 seconds, between about 0.1 seconds and about 6 seconds, or between about 0.1 seconds and about 1 second, depending on the flow rate and the wafer surface area. In some implementations, this step in the plasma-enhanced ALD cycle may be referred to as a “flash” operation to convert precursor material on the photoresist using plasma in a relatively short amount of time. In some implementations, a carrier or diluting gas flows during the reactant material delivery phase. In some implementations, a purge phase may follow a reactant material delivery, where carrier or diluting gas may continue to flow. Precursor flow is turned off and no plasma is ignited during the purge phase. The ALD cycle, including operations of introducing a dose of the precursor and converting the precursor, may be repeated until a desired thickness of the protective coating is formed on the photoresist.

The protective coating may include any suitable material for protecting the photoresist from ion-beam or electron-beam irradiation damage and for providing sufficient imaging contrast against the photoresist during inspection. In some implementations, the protective coating is a dielectric material having a dielectric constant different than a material of the photoresist. In some implementations, the protective coating includes an oxide, a nitride, or a mixture thereof. For example, the protective coating includes silicon oxide (SiOₓ).

In some implementations, the protective coating is highly conformal. In some implementations, the protective coating has a conformality of at least 80%, or between about 80% and about 100%. Conformality may be calculated by comparing an average thickness of a deposited protective coating on a bottom, sidewall, or top of a feature to an average thickness of the deposited protective coating on a bottom, sidewall, or top of a feature. For example, conformality may be calculated by dividing the average thickness of the deposited protective coating on the sidewall of a photoresist feature by the average thickness of the deposited protective coating at the top of the photoresist feature and multiplying it by 100 to obtain a percentage.

The processing conditions in the reactor under which the protective coating is formed on the photoresist enable the protective coating to be formed with negligible damage to the photoresist. Ordinarily, photoresist materials and other soft materials are sensitive to plasma and susceptible to damage or distortion as a result of exposure to radicals, ions, photons, electrons, and other charged species. Surprisingly, a protective coating may be deposited on a photoresist under mild plasma processing conditions with minimal damage and distortion to the photoresist. Various parameters can be tuned and optimized to provide the protective coating so that it is substantially non-damaging to the underlying photoresist.

As used herein, “substantially non-damaging” can refer to substantially retaining the original shape, original feature height, original feature volume, and original CD of the photoresist, and “substantially retaining” throughout this disclosure can refer to values within plus or minus 15 percent of the originally stated value. As used herein, the feature height may refer to the vertical dimension or thickness of a photoresist feature. For example, the feature height may be calculated from a bottom to a top surface of the photoresist feature as measured from a center of a lateral dimension (e.g., width or length) of the photoresist feature. As used herein, the CD or minimum CD can refer to the size of the smallest geometrical feature such as the narrowest width or narrowest length of a photoresist feature.

In some implementations, the reactor in which the protective coating is deposited is a plasma reactor such as an inductively-coupled plasma (ICP) processing reactor. In some implementations, a Kiyo™ reactor, produced by Lam Research Corporation of Fremont, Calif., is an example of a suitable reactor that may be used as the plasma reactor. A description of the plasma reactor is discussed in detail below with respect to FIGS. 12 and 13.

Various plasma parameters may be controlled in depositing the protective coating so that the deposition is substantially non-damaging to the photoresist. Examples of plasma parameters include but are not limited to plasma power, frequencies, duty cycles, plasma density, plasma potential, gas flows, and chamber pressure. One or more of these plasma parameters may influence the flux, density, direction, and/or energy of ions, radicals, photons, electrons, and other charged species at the wafer surface or adjacent to the wafer surface. By controlling one or more of these plasma parameters, how much the photoresist is exposed to ions, radicals, photons, electrons, and other charged species may be minimized. Even though photoresist materials exposed to plasma can induce chemical and thermal energy that can change the structure and shape of a photoresist, the plasma conditions can be controlled to minimize such changes. In some implementations, an applied plasma power may be less than about 500 W, between about 10 W and about 300 W, or between about 50 W and about 300 W. In some implementations, the applied plasma power may be supplied by a radio-frequency (RF) power supply to a coil in an ICP processing reactor. In some implementations, the one or more plasma parameters may be controlled so that the condition under which the protective coating is deposited includes a maximum ion density or maximum ion energy. For example, the condition can include a maximum ion density of less than about 3.0×10¹⁰ ions/cm³, less than about 2.0×10¹⁰ ions/cm³, or less than about 1.0×10¹⁰ ions/cm³. The ion density may depend on various other parameters, such as gas flows, plasma power, and chamber pressure.

Temperature settings, including wafer temperature and/or chamber temperature, may be controlled so that deposition of the protective coating is substantially non-damaging to the photoresist. Photoresist materials and soft materials may be sensitive to temperature, and such materials may degrade, distort, or deform under elevated temperatures. Thermal energy induced from elevated temperatures can change the structure and shape of a photoresist. Accordingly, depositing the protective coating may occur under relatively low wafer temperatures and chamber temperatures. In some implementations, a wafer temperature may be less than about 70° C., between about 10° C. and about 60° C., or between about 20° C. and about 60° C.

Application of plasma power may activate a reactant gas to form plasma including radicals and/or ions of the reactant gas. For example, delivery of a reactant gas may be part of an ALD cycle as described above. The reactant gas may be flowed with a carrier or diluting gas. The reactant gas and/or diluting gas may be chosen in depositing the protective coating so that deposition is substantially non-damaging to the photoresist. In some implementations, the reactant gas may include an oxygen-containing reactant such as oxygen (O₂), water (H₂O), carbon dioxide (CO₂), carbon monoxide (CO), nitrous oxide (N₂O), nitric oxide (NO), sulfur dioxide (SO₂), ozone, (O₃), oxygen-containing hydrocarbons, or combinations thereof. In some implementations, the reactant gas may include a nitrogen-containing reactant such as nitrogen (N₂), ammonia (NH₃), nitrous oxide (N₂O), nitric oxide (NO), hydrazine (N₂H₄), diazene (N₂H₂), nitrogen-containing hydrocarbons including various amines, or combinations thereof. The oxygen-containing reactant and/or nitrogen-containing reactant may be introduced along with a carrier or diluting gas. For example, the carrier or diluting gas may include helium (He) or argon (Ar).

In some implementations, depositing the protective coating may include flowing a precursor into the reactor. For example, precursor flow may be introduced as part of an ALD cycle as described above. In some implementations, the photoresist may be exposed to the precursor and radicals and ions of the reactant gas may react with the precursor to form the protective coating. Not only can the choice of a reactant gas affect the photoresist, but the choice of the precursor can also affect the photoresist. In some implementations, the precursor can include a silicon-containing precursor, a carbon-containing precursor, or a metal-containing precursor. Examples of silicon-containing precursors include but are not limited to silanes, halosilanes, and aminosilanes.

Flow rates of the precursor gas flow, the reactant gas flow, or the diluting gas flow may affect whether deposition of the protective coating is substantially non-damaging to the photoresist or not. In some implementations, a flow rate of the reactant gas may be between about 100 sccm and about 5000 sccm, or between about 200 sccm and about 2000 sccm.

In some implementations, chamber pressure in the reactor may affect whether deposition of the protective coating is substantially non-damaging to the photoresist or not. For example, the chamber pressure may be controlled to minimize ionization and ion bombardment. In some implementations, the chamber pressure may be at least 10 mTorr, or between about 10 mTorr and about 100 mTorr.

In some implementations, pulse times for plasma exposure in an ALD cycle may be controlled so that deposition of the protective coating on the photoresist is substantially non-damaging. Specifically, the duration of exposure to plasma of an oxygen-containing reactant or nitrogen-containing reactant can be sufficiently short to minimize damage to the underlying photoresist. However, the duration of exposure to plasma is sufficient to convert the precursor to an oxide or nitride material in the ALD cycle. In some implementations, the pulse times for exposing the precursor to plasma may be between about 0.05 seconds and about 6 seconds, or between about 0.1 seconds and about 1 second, or between about 0.2 seconds and about 1 second per ALD cycle. The “flash” operation for converting precursor material in an ALD cycle as described above may relate to the pulse times for plasma exposure.

In some implementations, a number of ALD cycles may be controlled so that deposition of the protective coating on the photoresist is substantially non-damaging. In some implementations, a number of ALD cycles may be between about 10 ALD cycles and about 150 ALD cycles, between about 50 ALD cycles and about 150 ALD cycles, or between about 70 ALD cycles and about 120 ALD cycles. The number of ALD cycles may correlate directly with a thickness of the deposited protective coating. The thickness of the protective coating can be controlled to minimize distortion or deformation of the photoresist. The protective coating can be sufficiently thick to protect against ion-beam or electron-beam irradiation that would otherwise distort or deform the photoresist. The protective coating can be sufficiently thin so as to not induce compressive stress that would otherwise distort or deform the photoresist. In some implementations, a thickness of the protective coating is between about 0.5 nm and about 20 nm, between about 1 nm and about 10 nm, or between about 1 nm and about 5 nm.

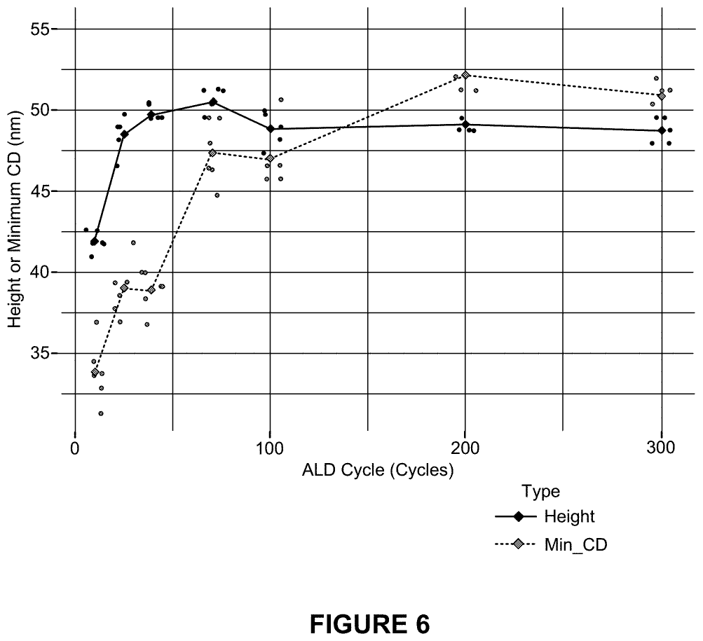

FIG. 6 shows a graph of minimum CD and feature height of a photoresist as a function of a number of ALD cycles applied in a non-damaging protective coating on the photoresist. The non-damaging coating may be deposited by plasma-enhanced ALD. As shown in FIG. 6, having too few ALD cycles results in reduced feature height and reduced minimum CD. The significant increase (e.g., spanning from 0 cycles to 70 cycles) in feature height and minimum CD is indicative of shrinkage to the minimum CD and feature height when there is an insufficient number of ALD cycles. Without being limited by any theory, an insufficient number of ALD cycles may correspond to a protective coating that is too thin to protect against ion-beam or electron-beam irradiation. Furthermore, having too many ALD cycles results in reduced feature height and increased minimum CD. The slight decrease in feature height and slight increase in minimum CD is indicative of shrinkage of the feature height and expansion of lateral dimensions with an increasing number of ALD cycles. Without being limited by any theory, an excess number of ALD cycles may correspond to an excess amount of thickness that induces compressive stress on the underlying photoresist. In FIG. 6, too few ALD cycles may occur at less than about 70 cycles and too many ALD cycles may occur at greater than about 120 cycles. An optimal process window for number of ALD cycles may be established for a plasma-enhanced ALD process on a photoresist that maximizes protection against ion-beam or electron-beam irradiation and minimizes compressive stress effects. The optimal process window may vary depending on a variety of factors such as precursor, reactant gas, plasma power, wafer temperature, photoresist material, etc. Though FIG. 6 illustrates minimum CD and feature height changes as a function of a number of ALD cycles, it will be understood that such minimum CD and feature height changes may be generalized as a function of deposition amount instead of ALD cycles.

Moreover, FIG. 6 shows that each of the photoresist feature height change and the photoresist critical dimension change is not greater than 15% with a sufficiently non-damaging protective coating. The photoresist may be deposited with a target height between about 55 nm and about 60 nm, and photoresist may be deposited with a target critical dimension between about 55 nm and about 60 nm. As shown in FIG. 6, an optimal non-damaging protective coating may be deposited on the photoresist that does not cause a reduction in photoresist feature height or a change in critical dimension to be greater than 15%.

FIGS. 7A-7C show TEM images of different oxide protective coatings on a photoresist, with the darker gray outlines indicating the oxide protective coating and the lighter gray outlines indicating the photoresist features. FIG. 7A shows a TEM image of an oxide protective coating on a photoresist deposited using a thermal ALD process. The thermal ALD process may convert precursor under elevated temperatures (e.g., 40° C. or greater) to form the oxide protective coating. The photoresist profile in FIG. 7A shows significant sidewall pullback and distortion. FIG. 7B shows a TEM image of an oxide protective coating on a photoresist deposited using a plasma-enhanced ALD process at reduced temperatures. The plasma-enhanced ALD process may convert precursor at reduced temperatures (e.g., 20° C. or less) to form the oxide protective coating. The photoresist profile in FIG. 7B shows less sidewall pullback and distortion compared to FIG. 7A. FIG. 7C shows a TEM image of an oxide protective coating on a photoresist deposited using a plasma-enhanced ALD process at reduced reactant gas flow rate. The flow rate of oxygen gas in FIG. 7B is 2000 sccm and the flow rate of oxygen gas in FIG. 7C is reduced to 200 sccm. The photoresist profile in FIG. 7C exhibits even less sidewall pullback and distortion compared to FIGS. 7A and 7B. Accordingly, the TEM images in FIGS. 7A-7C demonstrate that not only can plasma-enhanced ALD deposited protective coatings reduce deformation and distortion in photoresist profiles compared to thermal ALD deposited protective coatings, but that reducing wafer temperature and reactant gas flow rate may further reduce deformation and distortion in photoresist profiles.

Returning to FIG. 5, at block 530 of the process 500, metrology is performed on the photoresist with the protective coating using a metrology tool. The protective coating provides scaffolding on the photoresist so that the photoresist can be accurately characterized. In other words, highly accurate profile information and/or structural information of the photoresist can be obtained with the assistance of the protective coating. Profile measurements and inspections of the photoresist can be performed using a metrology tool. Examples of metrology tools include but are not limited to CDSEM, OCD, AFM, SEM, STEM, and TEM.

At block 530 of the process 500, the wafer may be subjected to after-development inspection and characterization. An output of the operation at block 530 is to provide images and/or data characterizing the two-dimensional and/or three-dimensional profile of features of the photoresist. In some implementations, features of the photoresist may be formed after photoresist material is exposed to radiation patterns through a photomask (reticle) and subsequently developed. A metrology result is produced by measuring features of the photoresist, where the measurements may be used to obtain profile information of the photoresist. Such measurements may be performed by microscopy (e.g., SEM, TEM, STEM, CDSEM, and AFM) or optical metrology. In some implementations, the metrology result is produced by performing reflectometry, dome scatterometry, angle-resolved scatterometry, small-angle X-ray scatterometry (SAXS), and/or ellipsometry on the wafer.

Metrology tools may be categorized by where they are conducted and what they do to the sample. Categories include in-situ, offline nondestructive, and destructive metrology. In-situ metrology includes, for example, reflectometry and ellipsometry. Offline nondestructive metrology includes, for example, single-wavelength and broadband OCD metrology or scatterometry, dome scatterometry, CD-SAXS, and CDSEM (top-down SEM). Destructive metrology includes, for example, XTEM, STEM, and TEM. Regardless of the category of the metrology tool, a metrology result may be produced that provides measured profiles of the photoresist.

In some implementations, the metrology is performed using a metrology tool that is part of the system or apparatus equipped with the reactor for depositing the protective coating. Having the metrology tool and the reactor as part of the same system or apparatus can increase throughput, minimize cost, and minimize additional damage or evolution of the protective coating during wafer transfers. In some implementations, the process 500 further includes transferring the wafer from the reactor to the metrology tool under vacuum conditions. This can minimize damage or evolution of the protective coating, including distortion as well as growth or stress due to water adsorption or reaction. In some implementations, the process 500 further includes transferring the wafer from the reactor to the metrology tool under atmospheric conditions. This can maximize throughput and minimize cost.

The protective coating is substantially non-damaging to the underlying photoresist so as to not significantly change the dimensions of the features of the photoresist. In addition, the protective coating allows for destructive metrology and/or electron microscopy-based metrology to be performed on the photoresist so that features of the photoresist can be accurately captured. When the photoresist is subject to destructive metrology and/or electron microscopy-based metrology, the dimensions of the features of the photoresist are substantially preserved. As used herein, “substantially preserved” dimensions may refer to less than 15% reduction in feature height, less than 15% change in feature volume, and/or less than 15% change in critical dimension.

In some implementations, performing metrology on the photoresist includes determining a profile of the photoresist. The profile of the photoresist may include two-dimensional or three-dimensional profiles of features of the photoresist. In some implementations, the profile of the photoresist may be used as inputs for a resist model or an etch model. For example, the profile of the photoresist determined by the metrology tool may be used as an input to train, optimize, and improve computerized profile models in a resist model or an etch model. Because the profiles of etched features are dependent on the profiles of photoresist features, accurate modeling of photoresist features can strongly influence the predictive capability and accuracy of etch models. In some implementations, the process 500 further includes providing the profile of the photoresist into an etch model for predicting an etch profile of an etch simulation. Therefore, accurate determination of the profile of the photoresist allows for tighter control in resist and/or etch modeling so that lithography techniques and etch processes can be improved. For example, accurate determination of the profile of the photoresist may be implemented in optical proximity correction (OPC) applications and/or etch profile models. That way, such applications and/or models do not have to guess as to what the photoresist actually looks like in their measurements, predictions, models, and calculations.

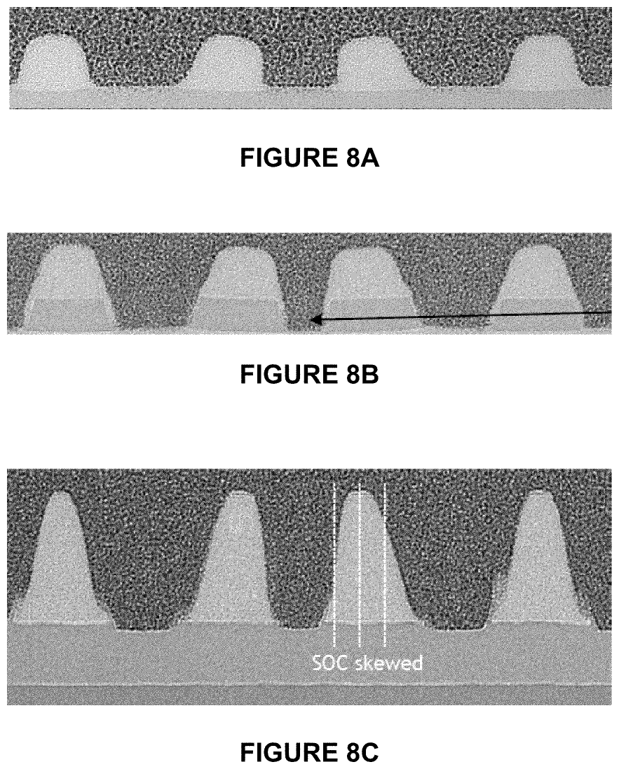

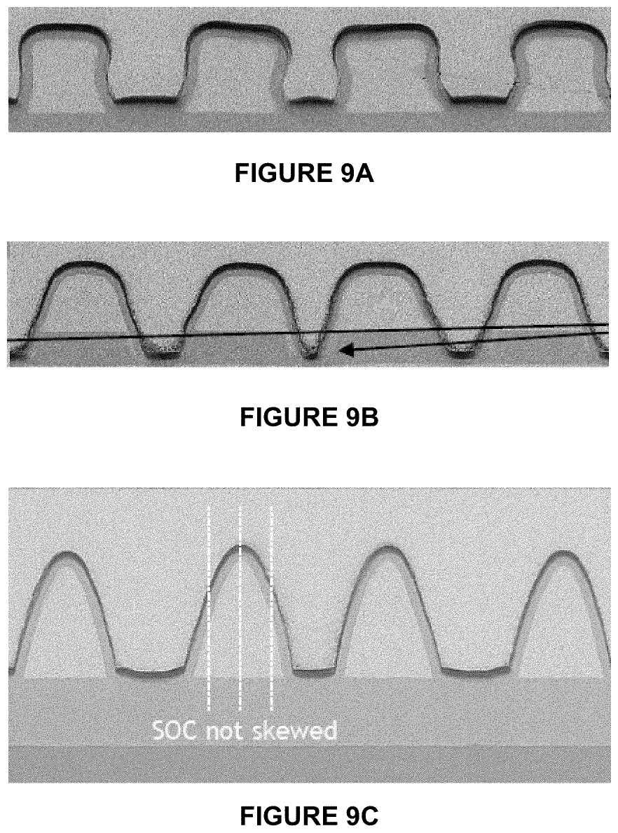

FIGS. 8A-8C show TEM images in a multiple patterning process with an electron-beam-based platinum coating on a photoresist. FIGS. 9A-9C show TEM images in a multiple patterning process with a non-damaging protective coating on a photoresist. Capturing an accurate profile of the photoresist may be important in performing patterning and etch processes of underlying layers. In comparing FIGS. 8A and 9A, the incoming photoresist profiles reveal different irregularly-shaped photoresist features. Such irregularities in the photoresist features may be accounted for in etching an underlying spin-on glass (SOG) layer in FIGS. 8B and 9B. In comparing FIGS. 8B and 9B, the etched features including the photoresist and the SOG layer reveal less distortion in FIG. 9B compared to FIG. 8B. The non-damaging protective coating may provide a more accurate initial depiction of the photoresist profile than the electron-beam-based platinum coating. An underlying spin-on carbon (SOC) layer is etched in FIGS. 8C and 9C. In comparing FIGS. 8C and 9C, the etched features including the photoresist, the SOG layer, and the SOC layer reveal less distortion in FIG. 9C compared to FIG. 8C. In other words, the etched features in FIG. 9C are not as skewed as the etched features in FIG. 8C. Utilization of damage-inducing coatings such as the electron-beam-based platinum coating may lead to inaccurate calibrations and calculations in resist and etch modeling. However, utilization of a non-damaging protective coating as described in the present disclosure provides better imaging and knowledge of ADI photoresist shapes and profiles, which can provide for improved resist modeling and etch modeling. The non-damaging protective coating may be deposited by plasma-enhanced ALD.

In FIG. 8A, the photoresist with the electron-beam-based platinum coating had a photoresist feature height of 31.6 nm and a width of 55.8 nm. In comparing the same photoresist in FIG. 7C with a plasma-enhanced ALD protective oxide coating, the photoresist with the plasma-enhanced ALD protective oxide coating had a photoresist feature height of 45.0 nm and a width of 56.2 nm. As a result, the photoresist with the electron-beam-based platinum coating shrunk in photoresist feature height by more than 10 nm, meaning that the photoresist feature height was reduced by more than 15%.

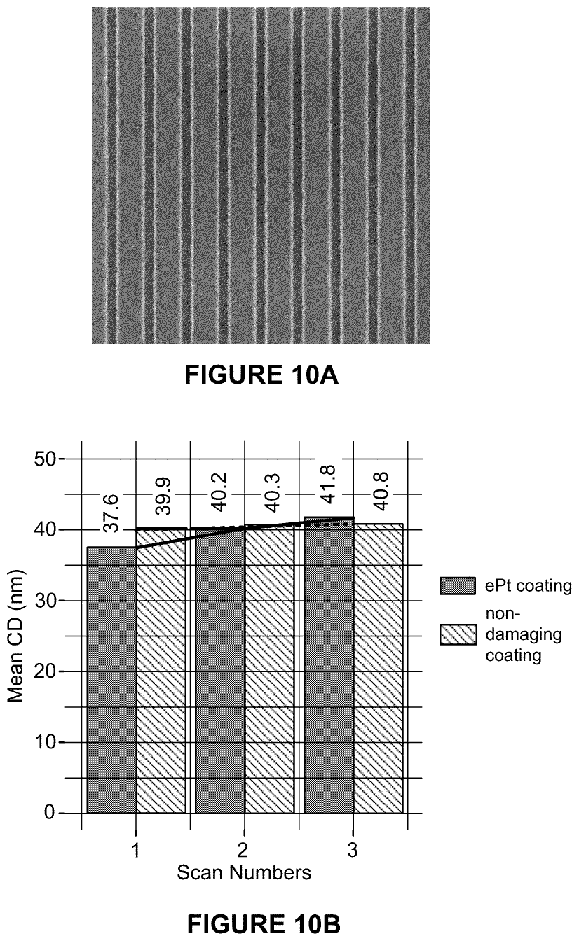

FIG. 10A shows a CDSEM image of photoresist lines on a wafer. CDSEM metrology can measure the dimensions of fine patterns formed on a wafer by electron-beam irradiation. CDSEM is also referred to as top-down SEM and can indicate changes in topographical profile of the photoresist lines. FIG. 10B shows a graph of mean CD measured across three scans of the CDSEM image in FIG. 10A for photoresist lines without a coating and for photoresist lines with a non-damaging protective coating. The non-damaging protective coating may be deposited by plasma-enhanced ALD. A first, second, and third scan of the photoresist lines without a coating produced a mean CD of 37.6 nm, 40.2 nm, and 41.8 nm, respectively. The first, second, and third scans yielded approximately a 2 nm difference per scan. In contrast, a first, second, and third scan of the photoresist lines with the non-damaging protective coating produced a mean CD of 39.9 nm, 40.3 nm, and 40.8 nm, respectively. The first, second, and third scans yielded approximately less than a 0.5 nm difference per scan.

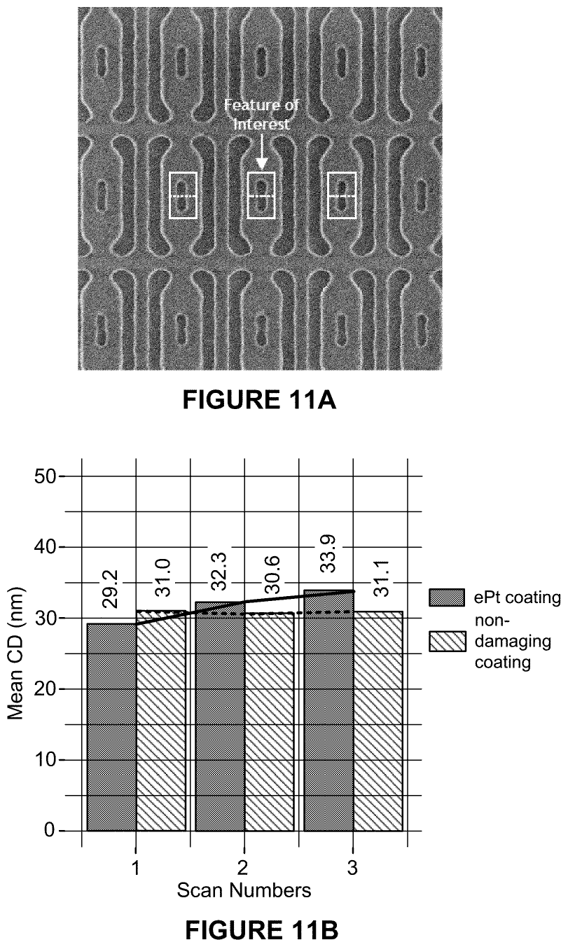

FIG. 11A shows a CDSEM image of photoresist features on a wafer. The CDSEM images can indicate changes in topographical profile of the photoresist features. FIG. 11B shows a graph of mean CD measured across three scans of the CDSEM image in FIG. 11A for photoresist features without a coating and for photoresist features with a non-damaging protective coating. The non-damaging protective coating may be deposited by plasma-enhanced ALD. A first, second, and third scan of the photoresist features without a coating produced a mean CD of 29.2 nm, 32.3 nm, and 33.9 nm, respectively. The first, second, and third scans yielded approximately a 2 nm difference per scan. In contrast, a first, second, and third scan of the photoresist features with the non-damaging protective coating produced a mean CD of 31.0 nm, 30.6 nm, and 31.1 nm, respectively. The first, second, and third scans yielded approximately less than a 0.5 nm difference per scan. Deposition of the protective coating of the present disclosure can yield more accurate and highly reliable measurements and profile information of photoresist features.

### Apparatus

FIG. 12 shows a schematic diagram of an example plasma processing apparatus for performing plasma-enhanced ALD operations. A Kiyo™ reactor, produced by Lam Research Corp. of Fremont, Calif., is an example of a suitable reactor that may be used to implement the techniques described herein. The inductively coupled plasma apparatus 1200 includes an overall reactor structurally defined by chamber walls 1201 and a window 1211. The chamber walls 1201 may be fabricated from stainless steel or aluminum. The window 1211 may be fabricated from quartz or other dielectric material. An optional internal plasma grid 1250 divides the overall reactor into an upper sub-chamber 1202 and a lower sub-chamber 1203. The plasma grid 1250 may include a single grid or multiple individual grids. In many embodiments, plasma grid 1250 may be removed, thereby utilizing a chamber space made of sub-chambers 1202 and 1203.

A chuck 1217 is positioned within the lower sub-chamber 1203 near the bottom inner surface. The chuck 1217 is configured to receive and hold a semiconductor wafer 1219 upon which the deposition process is performed. The chuck 1217 can be an electrostatic chuck for supporting the wafer 1219 when present. In some embodiments, an edge ring (not shown) surrounds chuck 1217, and has an upper surface that is approximately planar with a top surface of a wafer 1219, when present over chuck 1217. The chuck 1217 also includes electrostatic electrodes for chucking and dechucking the wafer. A filter and DC clamp power supply (not shown) may be provided for this purpose. Other control systems for lifting the wafer 1219 off the chuck 1217 can also be provided. The chuck 1217 can be electrically charged using an RF power supply 1223. The RF power supply 1223 is connected to matching circuitry 1221 through a connection 1227. The matching circuitry 1221 is connected to the chuck 1217 through a connection 1225. In this manner, the RF power supply 1223 is connected to the chuck 1217.

A coil 1233 is positioned above window 1211. The coil 1233 is fabricated from an electrically conductive material and includes at least one complete turn. The exemplary coil 1233 shown in FIG. 12 includes three turns. The cross-sections of coil 1233 are shown with symbols, and coils having an “X” extend rotationally into the page, while coils having a “*” extend rotationally out of the page. An RF power supply 1241 is configured to supply RF power to the coil 1233. In general, the RF power supply 1241 is connected to matching circuitry 1239 through a connection 1245. The matching circuitry 1239 is connected to the coil 1233 through a connection 1243. In this manner, the RF power supply 1241 is connected to the coil 1233. An optional Faraday shield 1249 is positioned between the coil 1233 and the window 1211. The Faraday shield 1249 is maintained in a spaced apart relationship relative to the coil 1233. The Faraday shield 1249 is disposed immediately above the window 1211. The coil 1233, the Faraday shield 1249, and the window 1211 are each configured to be substantially parallel to one another. The Faraday shield may prevent metal or other species from depositing on the dielectric window of the plasma chamber.

Process gases may be supplied through a main injection port 1260 positioned in the upper chamber and/or through a side injection port 1270, sometimes referred to as an STG. A vacuum pump, e.g., a one or two stage mechanical dry pump and/or turbomolecular pump 1240, may be used to draw process gases out of the process chamber and to maintain a pressure within the process chamber 1200 by using a closed-loop-controlled flow restriction device, such as a throttle valve (not shown) or a pendulum valve (not shown), during operational plasma processing.

During operation of the apparatus, one or more reactant gases and precursor gases may be supplied through injection ports 1260 and/or 1270. In certain embodiments, gas may be supplied only through the main injection port 1260, or only through the side injection port 1270. In some cases, the injection ports may be replaced by showerheads. The Faraday shield 1249 and/or optional grid 1250 may include internal channels and holes that allow delivery of process gases to the chamber. Either or both of Faraday shield 1249 and optional grid 1250 may serve as a showerhead for delivery of process gases.

Radio frequency power is supplied from the RF power supply 1241 to the coil 1233 to cause an RF current to flow through the coil 1233. The RF current flowing through the coil 1233 generates an electromagnetic field about the coil 1233. The electromagnetic field generates an inductive current within the upper sub-chamber 1202. The physical and chemical interactions of various generated ions and radicals with the wafer 1219 may convert adsorbed precursor material on the wafer 1219.

If the plasma grid 1250 is used such that there is both an upper sub-chamber 1202 and a lower sub-chamber 1203, the inductive current acts on the gas present in the upper sub-chamber 1202 to generate an electron-ion plasma in the upper sub-chamber 1202. The optional internal plasma grid 1250, if present, may act to limit the number of hot electrons in the lower sub-chamber 1203. In some embodiments, the apparatus is designed and operated such that the plasma present in the lower sub-chamber 1203 is an ion-ion plasma. In other embodiments, the apparatus may be designed and operated such that the plasma present in the lower sub-chamber 1203 is an electron-ion plasma. Internal plasma grids and ion-ion plasma are further discussed in U.S. patent application Ser. No. 14/082,009, filed Nov. 15, 2013, and titled “INTERNAL PLASMA GRID FOR SEMICONDUCTOR FABRICATION,” and in U.S. Pat. No. 9,245,761, each of which is herein incorporated by reference in its entirety.

Volatile byproducts may be removed from the lower-sub chamber 1203 through port 1222. The chuck 1217 disclosed herein may operate at temperatures ranging between about 0° C. and about 250° C., or between about 20° C. and about 60° C. In some cases, the chuck 1217 may also operate at lower temperatures, for example when the chuck 1217 is actively chilled. In such cases the chuck 1217 may operate at substantially lower temperatures, as desired. The temperature will depend on the deposition process operation and specific recipe. In some embodiments, the chamber 1201 may operate at pressures in the range of between about 1 mTorr and about 100 mTorr. In certain embodiments, the pressure may be higher.

Chamber 1201 may be coupled to facilities (not shown) when installed in a clean room or a fabrication facility. Facilities include plumbing that provide processing gases, vacuum, temperature control, and environmental particle control. These facilities are coupled to chamber 1201, when installed in the target fabrication facility. Additionally, chamber 1201 may be coupled to a transfer chamber that allows robotics to transfer semiconductor wafers into and out of chamber 1201 using typical automation.

In some embodiments, a system controller 1230 (which may include one or more physical or logical controllers) controls some or all of the operations of the reactor. The system controller 1230 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the system controller 1230 or they may be provided over a network. In certain embodiments, the system controller 1230 executes system control software.

In some cases, the system controller 1230 controls gas concentration, wafer movement, and/or the power supplied to the coils 1233 and/or electrostatic chuck 1217. The system controller 1230 may control the gas concentration by, for example, opening and closing relevant valves to produce one or more inlet gas stream that provide the necessary reactant(s) at the proper concentration(s). The wafer movement may be controlled by, for example, directing a wafer positioning system to move as desired. The power supplied to the coils 1233 and/or chuck 1217 may be controlled to provide particular RF power levels. Similarly, if the internal grid 1250 is used, any RF power applied to the grid may be adjusted by the system controller 1230.

The system controller 1230 may control these and other aspects based on sensor output (e.g., when power, potential, pressure, etc. reach a certain threshold), the timing of an operation (e.g., opening valves at certain times in a process), or based on received instructions from the user. An example controller is further discussed below.

FIG. 13 shows a top view of a schematic diagram of an example semiconductor process cluster architecture with various modules. The semiconductor process cluster architecture with various modules interfaces with a vacuum transfer module 1338 (VTM). The arrangement of transfer modules to “transfer” wafers among multiple storage facilities and processing modules may be referred to as a “cluster tool architecture” system. Airlock 1330, also known as a loadlock or transfer module, is shown in VTM 1338 with four modules 1320a-1320d, which may be individually optimized to perform various fabrication and/or metrology processes. By way of example, modules 1320a-1320d may be implemented to perform substrate etching, substrate deposition, ion implantation, wafer cleaning, sputtering, metrology, and/or other semiconductor processes. At least one of the modules (any of 1320a-1320d) may be implemented as deposition module for depositing a protective coating disclosed herein, and at least one of the modules (any of 1320a-1320d) may be implemented as a metrology or measurement module disclosed herein. Airlock 1330 and module 1320 may be referred to as “stations.” Each station has a facet 1336 that interfaces the station to VTM 1338. Inside each facet, sensors 1-18 are used to detect the passing of wafer 1326 when moved between respective stations.

Robot 1322 transfers wafer 1326 between stations. In one embodiment, robot 1322 has one arm, and in another embodiment, robot 1322 has two arms, where each arm has an end effector 1324 to pick wafers such as wafer 1326 for transport. Front-end robot 1332, in atmospheric transfer module (ATM) 1340, is used to transfer wafers 1326 from cassette or Front Opening Unified Pod (FOUP) 1334 in Load Port Module (LPM) 1342 to airlock 1330. Module center 1328 inside process module 1320 is one location for placing wafer 1326. Aligner 1344 in ATM 1340 is used to align wafers.

In an exemplary processing method, a wafer is placed in one of the FOUPs 1334 in the LPM 1342. Front-end robot 1332 transfers the wafer from the FOUP 1334 to an aligner 1344, which allows the wafer 1326 to be properly centered before it is processed. After being aligned, the wafer 1326 is moved by the front-end robot 1332 into an airlock 1330. Because airlock modules have the ability to match the environment between an ATM and a VTM, the wafer 1326 is able to move between the two pressure environments without being damaged. From the airlock module 1330, the wafer 1326 is moved by robot 1322 through VTM 1338 and into one of the modules 1320a-1320d. In order to achieve this wafer movement, the robot 1322 uses end effectors 1324 on each of its arms. Once the wafer 1326 has been processed, it is moved by robot 1322 from the modules 1320a-1320d to an airlock module 1330. From here, the wafer 1326 may be moved by the front-end robot 1332 to one of the FOUPs 1334 or to the aligner 1344. In some implementations, a wafer may be transferred between a deposition module and a metrology module through VTM 1338 under vacuum conditions. In some implementations, a wafer may be transferred between a deposition module and a metrology module through ATM 1340 under atmospheric conditions.

It should be noted that the computer controlling the wafer movement can be local to the cluster architecture, or can be located external to the cluster architecture in the manufacturing floor, or in a remote location and connected to the cluster architecture via a network.

In some implementations, a controller is part of a system, which may be part of the above-described examples. The controller may be configured with instructions for performing any of foregoing operations, such as: receiving a wafer having a photoresist in a deposition module, conformally depositing a protective coating on the photoresist, where the protective coating is conformally deposited in the deposition module operated under conditions with a wafer temperature being between about 20° C. and about 60° C. and a plasma power being between about 10 W and about 300 W, where conformally depositing the protective coating reduces a feature height of the photoresist by less than about 15%, changes a feature volume of the photoresist by less than about 15%, and changes a critical dimension of the photoresist by less than about 15%, and performing metrology on the photoresist with the photoresist in a metrology tool. In some implementations, conformally depositing the protective coating reduces a feature height by less than about 12% or less than about 10%, changes a feature volume of the photoresist by less than about 12% or less than about 10%, or changes a critical dimension of the photoresist by less than about 12% or less than about 10%. Such systems that the controller, deposition module, and metrology module are a part of can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, a metrology chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Conclusion

In the foregoing description, numerous specific details are set forth to provide a thorough understanding of the presented implementations. The disclosed implementations may be practiced without some or all of these specific details. In other instances, well-known process operations have not been described in detail to not unnecessarily obscure the disclosed implementations. While the disclosed implementations are described in conjunction with the specific implementations, it will be understood that it is not intended to limit the disclosed implementations.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of characterizing a photoresist, the method comprising:
receiving a wafer having a photoresist;
conformally depositing a protective coating on the photoresist, wherein the protective coating is conformally deposited in a reactor operated under conditions with a wafer temperature being less than about 70° C. and a plasma power being less than about 500 W, wherein depositing the protective coating reduces a feature height of the photoresist by less than about 15%, changes a feature volume of the photoresist by less than about 15%, and/or changes a critical dimension of the photoresist by less than about 15%; and
performing metrology on the photoresist with the protective coating using a metrology tool, wherein performing metrology on the photoresist includes exposing the wafer to an ion-beam or electron-beam irradiation.

2. The method of claim 1, wherein conformally depositing the protective coating on the photoresist includes depositing the protective coating by atomic layer deposition (ALD).

3. The method of claim 2, wherein depositing by ALD includes:
introducing a precursor to adsorb on the photoresist;
converting the precursor with a plasma to form an adsorption-limited amount of the protective coating on the photoresist; and
repeating operations of introducing the precursor and converting the precursor to conformally deposit the protective coating on the photoresist.

4. The method of claim 3, wherein converting the precursor with the plasma includes:
flowing an oxygen-containing reactant and/or a nitrogen-containing reactant to the reactor; and
igniting a plasma to form an oxidizing plasma and/or nitriding plasma.

5. The method of claim 4, wherein a flow rate of oxygen-containing reactant or a nitrogen-containing reactant is between about 200 sccm and about 2000 sccm.

6. The method of claim 3, wherein a number of ALD cycles in repeating the operations of introducing the precursor and converting the precursor includes between about 10 ALD cycles and about 150 ALD cycles.

7. The method of claim 3, wherein converting the precursor with plasma includes exposing the precursor to plasma for a duration between about 0.1 seconds and about 1 second.

8. The method of claim 1, wherein the protective coating includes an oxide, a nitride, or a mixture thereof, the protective coating having a dielectric constant that is different than the photoresist.

9. The method of claim 8, wherein the protective coating includes silicon oxide (SiOₓ).

10. The method of claim 1, wherein the metrology tool is selected from the group consisting of: a transmission electron microscope (TEM), a scanning electron microscope (SEM), a scanning transmission electron microscope (STEM), and a critical dimension scanning electron microscope (CDSEM).

11. The method of claim 1, wherein characterizing the photoresist includes determining a profile of the photoresist for a resist model.

12. The method of claim 11, further comprising:
providing the profile of the photoresist into an etch model for predicting an etch profile of an etch simulation.

13. The method of claim 11, further comprising:
optimizing the resist model using the profile of the photoresist characterized by the metrology tool.

14. The method of claim 1, wherein the conditions for conformally depositing the protective coating includes a maximum ion density of less than about 1.0×10¹⁰ ions/cm³.

15. The method of claim 1, wherein the conditions for conformally depositing the protective coating includes the wafer temperature being between about 20° C. and about 60° C., and the plasma power being between about 10 W and about 300 W.

16. The method of claim 1, wherein a CD critical dimension of the photoresist is equal to or less than about 20 nm.

17. (canceled)

18. The method of claim 1, wherein a step coverage of the protective coating on the photoresist is at least 80%.

19. The method of claim 1, wherein performing the metrology and conformally depositing the protective coating occur on a system that includes both the reactor and the metrology tool.

20. The method of claim 19, further comprising:
transferring the wafer from the reactor to the metrology tool under vacuum conditions.

21. The method of claim 19, further comprising:
transferring the wafer from the reactor to the metrology tool under atmospheric conditions.

22. A system comprising:
a deposition module;
a metrology module; and
a controller configured with instructions for performing the following operations:
receiving a wafer having a photoresist in the deposition module;
conformally depositing a protective coating on the photoresist, wherein the protective coating is conformally deposited in the deposition module operated under conditions with a wafer temperature being between about 20° C. and about 60° C. and a plasma power being between about 10 W and about 300 W, wherein conformally depositing the protective coating reduces a feature height of the photoresist by less than about 15%, changes a feature volume of the photoresist by less than about 15%, and/or changes a critical dimension of the photoresist by less than about 15%; and
performing metrology on the photoresist with the photoresist in the metrology tool, wherein performing metrology on the photoresist includes exposing the wafer to an ion-beam or electron-beam irradiation.
